(19) United States
(12) Patent Application Publication
(10) Pub. No.: US 2013/0237009 A1
(43) Pub. Date: Sep. 12, 2013

(54) METHOD FOR MANUFACTURING A GATE-CONTROL DIODE SEMICONDUCTOR DEVICE

(71) Applicants: Pengfei Wang, Shanghai (CN); Xi Lin, Shanghai (CN); Qingqing Sun, Shanghai (CN); Wei Zhang, Shanghai (CN)

(72) Inventors: Pengfei Wang, Shanghai (CN); Xi Lin, Shanghai (CN); Qingqing Sun, Shanghai (CN); Wei Zhang, Shanghai (CN)

(21) Appl. No.: 13/554,425

(22) Filed: Jul. 20, 2012

(30) Foreign Application Priority Data
Mar. 11, 2012 (CN) 201210061478.6

(51) Int. Cl. H01L 21/336

(52) U.S. Cl. 438/104; 257/E21.409

(57) ABSTRACT

The present invention belongs to the technical field of semiconductor device manufacturing, and specifically relates to a method for manufacturing a gate-control diode semiconductor device. The present invention manufactures gate-control diode semiconductor devices through a low-temperature process, features a simple process, low manufacturing cost, and capacity of manufacturing gate-control diode devices able to reduce the chip power consumption through advantages of high driving current and small sub-threshold swing. The method for manufacturing a gate-control diode semiconductor device proposed by the present invention is especially applicable to the manufacturing of reading & writing devices having flat panel displays and phase change memory, and semiconductor devices based on flexible substrates.

### CROSS-REFERENCE TO RELATED APPLICATION

This application claims priority to Chinese Patent Application No. CN 201210061478.6 filed on Mar. 11, 2012, the entire content of which is incorporated by reference herein.

### BACKGROUND OF THE INVENTION

1. Technical Field

The present invention belongs to the technical field of semiconductor device manufacturing, relates to a method for manufacturing a semiconductor device, and more especially, to a method for manufacturing a gate-control diode semiconductor device.

2. Description of Related Art

With the continuous development of integrated circuit, the size of the Metal-Oxide-Semiconductor Field Effect Transistor (MOSFET) is becoming smaller and smaller, and the transistor density on unit array is becoming higher and higher. Today, the technology node of integrated circuit devices is about 45 nm and the leakage current between the source and the drain of the MOSFET is increasing rapidly with the decrease of channel length. Moreover, the minimum sub-threshold swing (SS) of the traditional MOSFET is limited to 60 mv/dec, which restricts the opening and closing speed of the transistor. On some chips of high integration density, the reduction of the device size means greater SS value. However, the high-speed chips require a smaller SS value to improve the device frequency as well as reduce the chip power consumption. When the channel length of the device decreases to smaller than 20 nm, a new-type of device shall be used to obtain a smaller leakage current and SS value, thus decreasing the chip power consumption. For example, the using of a tunneling field effect transistor can reduce the leakage current between the source and the drain.

FIG. 1 is the structural view of a planar tunneling field effect transistor. Wherein a drain region 102 and a source region 103 are formed in a substrate 101, and 104 and 105 show the gate dielectric layer and gate electrode of the device respectively. The operation methods of different types of tunneling field effect transistors (p-type and n-type) are different. For instance, for an n-type tunneling field effect transistor, the source region is of p-type doping, the drain region is of n-type doping and the transistor is turned on when the gate and drain are applied with a positive voltage respectively. In this case, the positive voltage of the drain causes a reverse-biased diode to form in the drain region and the source region, thus reducing the leakage current. The energy band of the intrinsic substrate region decreases due to the positive voltage of the gate, thus the energy band between the substrate and the source region becomes much steeper, the distance between the conduction band and the valence band reduces, thus the valence band electrons of the source region is easy to tunnel to the conduction region of the substrate intrinsic region, and finally forming a channel current. However, with the decreasing of leakage current of the tunneling field effect transistor, its driving current also decreases, so it is also faced with the challenge of how to improve the driving current.

### BRIEF SUMMARY OF THE INVENTION

The present invention aims at providing a method for manufacturing a gate-control diode semiconductor device capable of increasing the driving current of the device and reducing the SS value so as to reduce the chip power consumption.

A method for manufacturing a gate-control diode semiconductor is provided in the present invention, including the following steps:

form a first kind of insulation film on a p-type silicon substrate;

etch the first kind of insulation film to form an active region window;

deposit a layer of n-type material on the first insulation film and the active region window as an active region which makes contact with the p-type subtract at the active region window;

cover the n-type active region to form a second kind of insulation film;

etch the first and second kinds of insulation film, form a drain contact window and a source contact window on both sides of the active region window respectively, thus the p-type subtract at the drain contact hole and the n-type active region at the source contact hole are exposed;

form a first kind of conductive film through deposition and etch it to form a drain electrode, a gate electrode and a source electrode, wherein the drain electrode is located on and fills the drain contract hole, the source electrode is located on and fills the source contact hole, the gate electrode is between the source electrode and the active region window located between the drain and gate electrodes, and the spacing between the gate electrode and the active region window is 20 nm-1 μm.

Further, the p-type active region includes but is not limited to a heavily-doped p-type silicon substrate, a p-type doping region formed in the silicon substrate and ZnO and NiO material which is formed on an insulation substrate and is doped with p-type impurity ions. The first kind of insulation film is of silicon oxide or silicon nitride. The second kind of insulation film is of SiO₂ or high dieletric constant material HfO₂. The first conductive film is of copper, tungsten, aluminum, titanium nitride or tantalum nitride.

The present invention manufacturing gate-control diode semiconductor devices through low-temperature process features simple process, low manufacturing cost and capacity of manufacturing gate-control diode devices with high driving current and small sub-threshold swing. The method for manufacturing a gate-control diode semiconductor device proposed by the present invention is especially applicable to the manufacturing of reading & writing devices having flat panel display and phase change memory, and semiconductor devices based on flexible substrate.

### BRIEF DESCRIPTION OF THE SEVERAL VIEWS OF THE DRAWINGS

FIG. 1 is the sectional view of the existing planar tunneling field effect transistor.

FIGS. 2-6 are the process flow diagrams of an embodiment of the method for manufacturing a gate-control diode semiconductor device disclosed in the present invention.

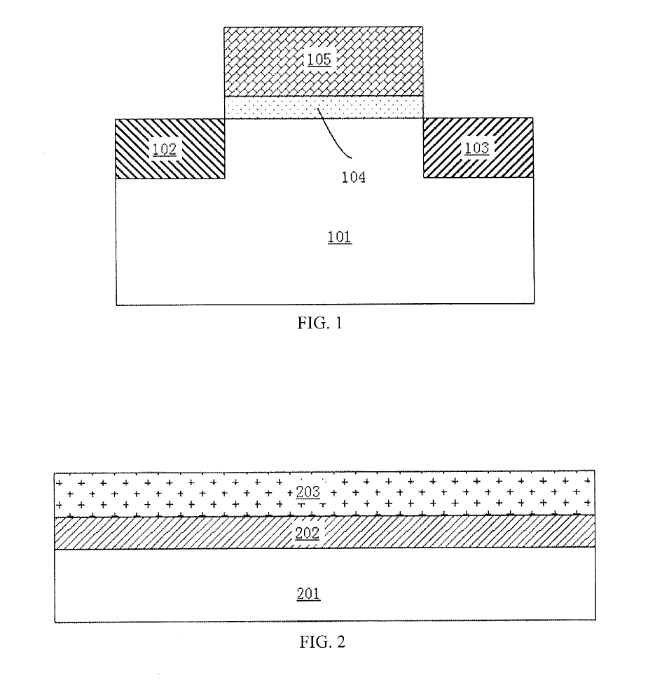

### DETAILED DESCRIPTION OF THE INVENTION

An exemplary embodiment of the present invention is further detailed herein by referring to the drawings. In the drawings, the thicknesses of the layers and regions are either zoomed in or out for the convenience of description, so they shall not be considered as the true size. Although these drawings cannot accurately reflect the true size of the device, they still reflect the relative positions among the regions and composition structures completely, especially the up-down and adjacent relations.

The reference diagrams are the schematic diagrams of the idealized embodiments of the present invention, so the embodiments shown in the present invention shall not be limited to specific shapes in areas shown in the drawings, while they shall include the obtained shapes such as the deviation caused by manufacturing. For instance, curves obtained through etching are often bent or rounded, while in the embodiments of the present invention, they are all presented in rectangles, and what the drawings present is schematic and shall not be considered as the limit to the present invention.

Firstly, prepare a solution with NaOH and water in proportion of 1:20, heat it to 80° C., immerse and rinse a polymide (P1) substrate with the solution for 20 min.Then immerse the P1 substrate in the isopropyl alcohol solution and conduct ultrasonic cleaning for 10 min. Finally, put the P1 substrate into deionized water, conduct ultrasonic cleaning for 10 min and blow-dry the P1 substrate surface with N2.

Deposit a silicon dioxide film 202 on the conditioned P1 substrate 201, then deposit a layer of NiO material doped with p-type impurity ions on the silicon dioxide film 202 and etch the NiO material deposited to form a p-type active region 203, as shown in FIG. 2.

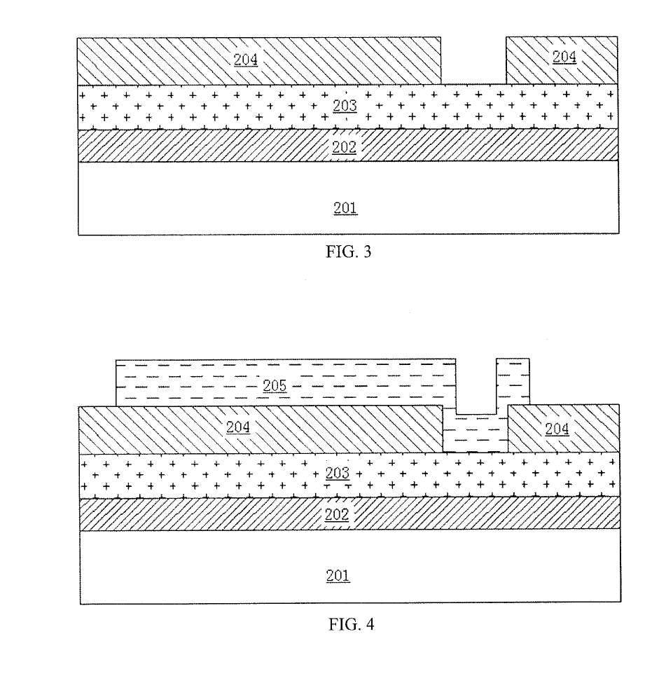

Next, deposit a silicon dioxide film 204 again, then deposit a layer of photoresist, form a pattern through masking film, exposal and development, and etch the silicon dioxide film 204 to form a window, the construction after removing the photoresist is as shown in FIG. 3.

Next, deposit a layer of ZnO material with a thickness of 5-10 nm through the ALD method and etch the ZnO material deposited to form an n-type active region 205, as shown in FIG. 4.

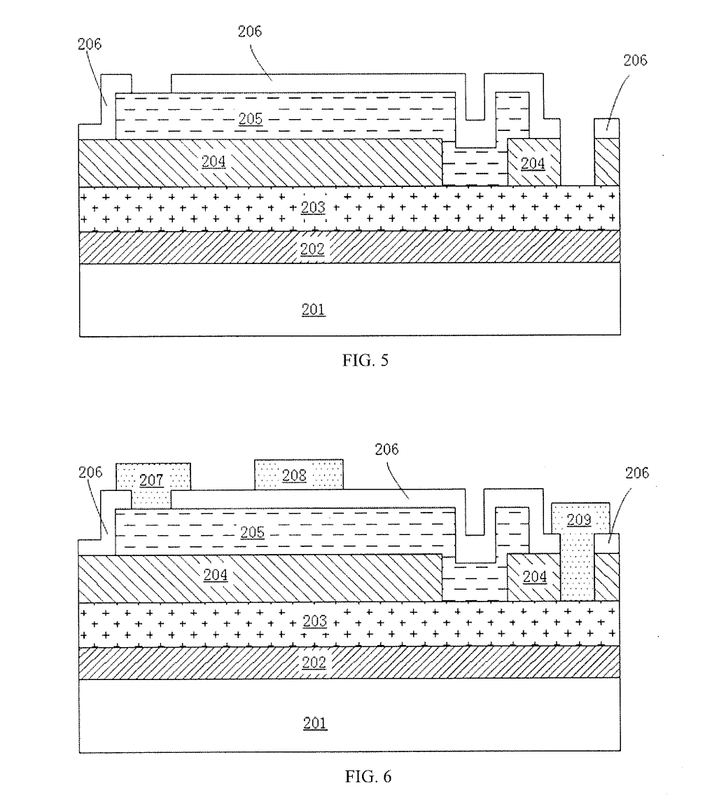

Then deposit a layer of high dielectric constant material 206 such as HfO2, then deposit a layer of photoresist again, form a pattern through masking film, exposal and development, and etch the high dielectric constant material 206 and the insulation film 204 to define the positions of the drain and the source, as shown in FIG. 5.

Finally, deposit a metal conductive film such as aluminum and then form a drain electrode 207, a gate electrode 208 and a source electrode 209 through photoetching and etching, as shown in FIG. 6. Since ZnO has the characteristics of n-type semiconductor, when the source and drain are applied with a forward bias, the device structure is equivalent to a forward-biased P+N junction structure and the device is conductive if the gate is applied with a positive voltage. If the gate is applied with a negative voltage, a p-type region is formed in the ZnO dielectric layer, the device is equivalent to a p-n-p-n junction structure and is cut off.

As described above, without deviating from the spirit and scope of the present invention, there may be many significantly different embodiments. It shall be understood that the present invention is not limited to the specific embodiments described in the Specification except those limited by the Claims herein.

What is claimed is:

1. A method for manufacturing a gate-control diode semiconductor device, characterized in that it includes the following steps:
form a first kind of insulation film on a p-type silicon substrate;
etch the first kind of insulation film to form an active region window;
deposit a layer of n-type material on the first insulation film and the active region window as an active region which makes contact with the p-type substrate at the active region window;
cover the n-type active region to form a second kind of insulation film;
etch the first and second kinds of insulation film, form a drain contact window and a source contact window on both sides of the active region window respectively, thus the p-type substrate at the drain contact hole and the n-type active region at the source contact hole are exposed;
form a first kind of conductive film through deposition and etch it to form a drain electrode, a gate electrode and a source electrode, wherein the drain electrode is located on and fills the drain contract hole, the source electrode is located on and fills the source contact hole, the gate electrode is between the source electrode and the active region window located between the drain and gate electrodes, and the spacing between the gate electrode and the active region window is 20 nm-1 μm.

2. The method for manufacturing a gate-control diode semiconductor device according to claim 1, characterized in that, the p-type active region includes a p-type silicon substrate, a p-type doping region formed on the silicon substrate and ZnO or NiO material which is formed on an insulation substrate and doped with p-type impurity ions.

3. The method for manufacturing a gate-control diode semiconductor device according to claim 1, characterized in that the first kind of insulation film is of silicon oxide or silicon nitride.

4. The method for manufacturing a gate-control diode semiconductor device according to claim 1, characterized in that the second kind of insulation film is of SiO₂ or HfO₂.

5. The method for manufacturing a gate-control diode semiconductor device according to claim 1, characterized in that the n-type active region is of ZnO material and with a thickness of 5-10 nm.

6. The method for manufacturing a gate-control diode semiconductor device according to claim 1, characterized in that the first kind of conductive film is of copper, tungsten, aluminum, titanium nitride or tantalum nitride.
